(19) United States
(12) Patent Application Publication
(10) Pub. No.: US 2025/0180640 A1
(43) Pub. Date: Jun. 5, 2025

(54) PLASMA INDUCED DAMAGE DETECTION OF A MEMORY DIE

(71) Applicant: Micron Technology, Inc., Boise, ID (US)

(72) Inventors: Aryo Santosa, Boise, ID (US); Ivo T. Wambeke, Boise, ID (US); James E. Davis, Meridian, ID (US); Joshua D. Tomayer, Meridian, ID (US); Chiara Cerafogli, Boise, ID (US); Kenneth W. Marr, Boise, ID (US)

(21) Appl. No.: 18/781,839

(22) Filed: Jul. 23, 2024

Related U.S. Application Data
(60) Provisional application No. 63/604,768, filed on Nov. 30, 2023.

(51) Int. Cl. G01R 31/28; H01L 23/10; H01L 23/31; H01L 25/10; H10B 80/00

(52) U.S. Cl. CPC G01R 31/2896; H01L 23/10; H01L 25/105; H10B 80/00; H01L 23/3171

(57) ABSTRACT

Methods, systems, and devices for techniques for coupled host and memory dies are described. In some examples, a device may include a memory die coupled with a substrate. Further, the device may include a die seal structure surrounding the memory die and coupled with the substrate. In some examples, the die seal may include multiple layers and the device may include an insulative material coupled with at least one layer of the multiples layers and a conductive material coupled with the insulative material. Additionally, the device may include a sensing circuit coupled with the conductive material. In some examples, the sensing circuit may be configured to generate a signal based on a charge accumulated in the conductive material.

### CROSS REFERENCE

The present Application for Patent claims priority to U.S. Patent Application No. 63/604,768 by Santosa et al., entitled “PLASMA INDUCED DAMAGE DETECTION OF A MEMORY DIE,” filed Nov. 30, 2023, which is assigned to the assignee hereof, and which is expressly incorporated by reference in its entirety herein.

### TECHNICAL FIELD

The following relates to one or more systems for memory, including plasma induced damage detection of a memory die.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports plasma induced damage detection of a memory die in accordance with examples as disclosed herein.

FIGS. 2A and 2B show examples of a component diagram that supports plasma induced damage detection of a memory die in accordance with examples as disclosed herein.

FIGS. 3A and 3B show examples of a circuit that supports plasma induced damage detection of a memory die in accordance with examples as disclosed herein.

### DETAILED DESCRIPTION

In some examples, a die seal may be formed around a memory die. The die seal may include conductive material and its purpose may be to protect the memory die from damage during manufacturing of the memory die. For example, multiple memory dies may be formed on a wafer and during manufacturing, the multiple memory dies may be separated from one another by cutting along scribe lines located between the memory dies. The die seal may provide structural support between the scribe line and the memory die such that the memory die is not damaged during the cutting. Further, a passivation layer may be formed on top of the memory die. The passivation layer may include dielectric material and may protect the memory die from plasma processes which may potentially damage electrical components of the memory die.

However, in some examples, the passivation layer may not fully cover the die seal (e.g., due to over-etching of the passivation layer), leaving at least a portion of the die seal exposed to plasma processes. As such, during the plasma processes, a significantly high voltage may be transmitted along the die seal. Charge in the die seal may build up and create high voltage and localized weak points in the die seal which may negatively impact the structural integrity of the die seal and increase the chance of contaminants getting through the die seal to the memory die (e.g., ions or moisture). Additionally or alternatively, the accumulated charge in the die seal may discharge through the die seal damaging one or more components of the memory die, among other failure modes.

To detect for a lateral over-etch or misalignment of the passivation layer and potential plasma induced charging on the die seal, a conductive antenna may be formed around the die seal. The conductive antenna may include a conductive material and may be coupled with an insulative material that surrounds the outside perimeter of the die seal. In some examples, the conductive antenna may include one or more segments. If the conductive antenna includes two or more segments, a gap between the segments of the two or more segments may be located at a corner of the die seal (e.g., a corner may refer to where two walls of the die seal meet). Further, each segment of the conductive antenna may be coupled with a sensing circuit. If at least a portion of the die seal is exposed to the plasma, charge will accumulate in the conductive antenna and the sensing circuit will generate a signal in response. The signal may indicate a lateral over-etch or misalignment of the passivation layer and potential plasma induced charging on the die seal. Upon detecting the signal, machinery or processes may be adjusted such that over-etching or misalignment of the passivation layer does not occur.

Features of the disclosure are illustrated and described in the context of systems and architectures. Features of the disclosure are further illustrated and described in the context of component diagrams, circuits, and flowcharts.

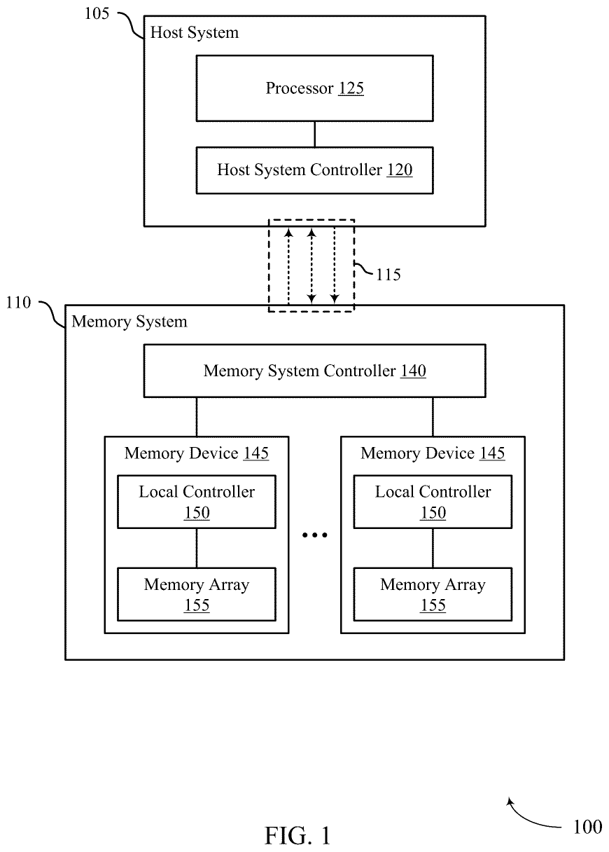

FIG. 1 illustrates an example of a system 100 that supports plasma induced damage detection of a memory die in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, a processing component) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 is dedicated to communicating one or more types of information, and channels 115 may include unidirectional channels, bidirectional channels, or both. For example, the channels 115 may include one or more command and address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A host system 105 or a memory system 110 may include one or more memory dies (e.g., memory devices 145). Around each memory die may be a die seal that protects the memory die from damage during manufacturing. Further, as described herein, around the border edges of the die seal may be a conductive antenna. The conductive antenna may be made of a conductive material and may include one or more segments. In some examples, a gap between segments of two or more segments of the conductive antenna may be located at a corner of the die seal (e.g., a corner may refer to where two walls of the die seal meet). Further, each segment of the conductive antenna may be coupled with a sensing circuit.

In some examples, each sensing circuit may be further coupled with a component of the memory die or an external testing device. During or after manufacturing, the testing device or the memory die may enter a test mode and detect a signal generated by the sensing circuit. If at least a portion of the die seal is not covered by a passivation layer and exposed to plasma processes during manufacturing, charge may accumulate in the conductive antenna and the sensing circuit will generate the signal in response. The signal may indicate a lateral over-etch or misalignment of the passivation layer deposited over the memory die and potential plasma induced charging on the die seal. Upon detecting the signal, machinery or processes may be adjusted such that the over-etching or misalignment of the passivation layer does not occur on a next round of wafers.

FIG. 1 illustrates a specific use-case of the disclosed plasma induced damage detection for a DRAM memory architecture. However, it is understood that the components and methods illustrated herein for plasma induced damage detection can be applied to any type of integrated circuit including, but not limited to, integrated circuits included in other memory architecture not discussed in FIG. 1 (e.g., NAND memory architecture or 3-d cross-point memory architecture).

In addition to applicability in systems as described herein, techniques for plasma induced damage detection of a memory die may be generally implemented to improve the sustainability of various electronic devices and systems. As the use of electronic devices has become increasingly widespread, the amount of energy used and environmental implications associated with production of electronic devices and device operation has increased. Further, waste associated with disposal of electronic devices may also be detrimental for various reasons. Implementing the techniques described herein may reduce impacts related to electronic devices by eliminating over-etching or misalignment of a passivation layer during manufacturing of memory dies, which may result in less “bad dies” being produced, thereby decreasing electronic waste, among other benefits.

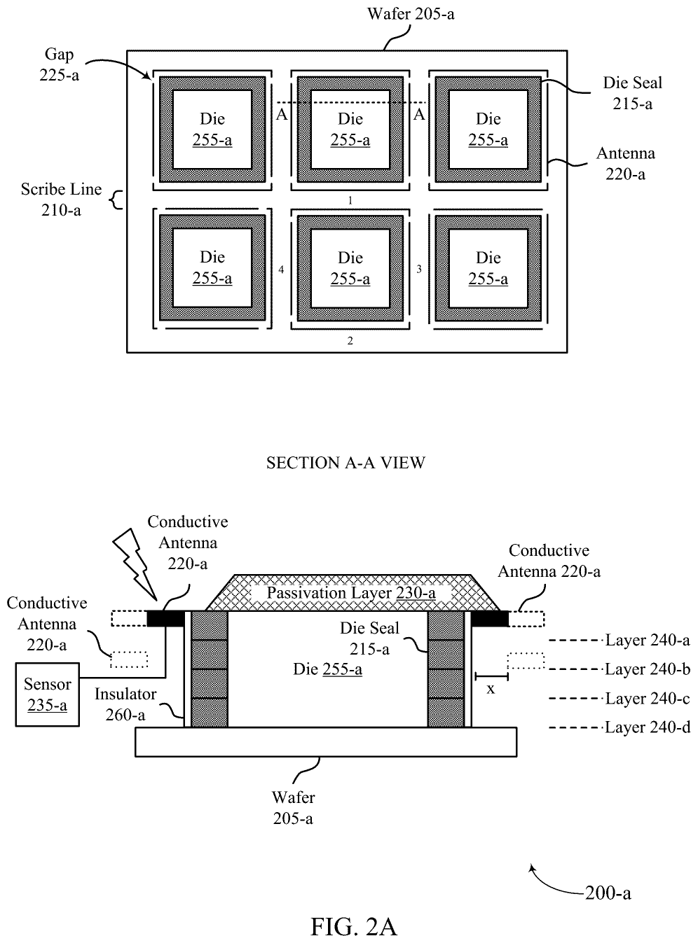

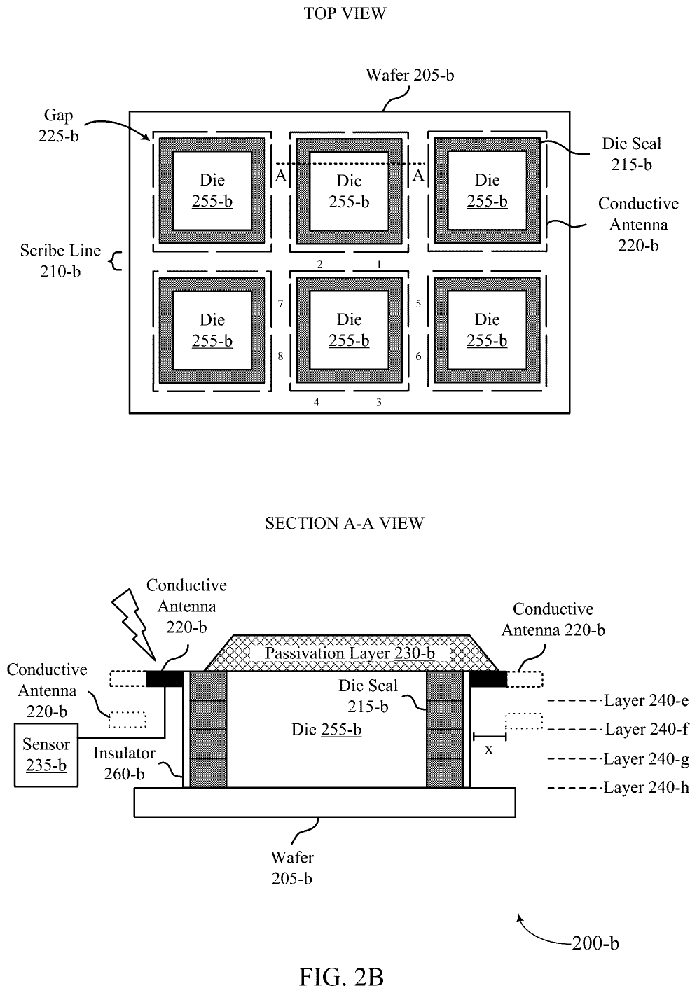

FIGS. 2A and 2B show examples of a component diagram 200 (e.g., a component diagram 200-a and a component diagram 200-b) that supports plasma induced damage detection of a memory die in accordance with examples as disclosed herein. In some examples, the component diagram 200-a and the component diagram 200-b may implement, or be implemented by, aspects of the system 100. For example, the component diagram 200-a and the component diagram 200-b may include dies 255 (e.g., dies 255-a and dies 255-b) which may be examples of memory devices 145 as described with reference to FIG. 1.

As shown in FIGS. 2A and 2B, multiple dies 255 may be formed on a wafer 205 (e.g., a wafer 205-a or a wafer 205-b). The wafer 205 may be described as a semiconductor substrate that is made up of a material such as silicon, germanium, silicon-germanium alloy, gallium arsenide, or gallium nitride. In addition to the dies 255, other components may be formed on the wafer 205. For example, die seals 215 (e.g., die seals 215-a and die seals 215-b) may be formed on the wafer 205. Die seals 215 may be described as structures whose purpose is to protect dies 255 during manufacturing. In some examples, during manufacturing, the wafer 205 may be cut along a scribe line 210 (e.g., a scribe line 210-a or a scribe line 210-b) to separate the dies 255 from one another and a die seal 215 may provide structural support to the die 255 such that the die 255 does not incur any damage from the cutting. It may be beneficial for the wafer 205 to be broken down into smaller chunks for different applications. To reduce stress on the wafer 205 during cutting, scribe lines 210 (or stress lines) may be formed between the dies 255 of the wafer 205. When force is applied to the wafer 205, stress may concentrate along the scribe lines 210 causing a fracture along the scribe lines 210 thus separating the dies 255 from one another.

In some examples, the die seal 215 may surround a respective die 255. In the example of FIGS. 2A and 2B, the die seal 215 may include four connected walls that may form a rectangular shape and each wall of the die seal 215 may include at least four surfaces. A first surface of the die seal 215 may be adjacent to (or coupled with) the wafer 205, a second surface of the die seal 215 may be opposite from the first surface, a third surface of the die seal 215 may be adjacent to (or coupled with) the respective die 255, and a fourth surface of the die seal 215 may be opposite from the third surface. Thus, the die seal 215 may be in contact with a respective die 255 via the third surface of the four walls of the die seal 215. Further, in some examples, the first surface of the die seal 215 may be planar with a bottom surface of the die 255 and the second surface of the die seal 215 may be planar with a top surface of the die 255.

In some examples, the die seal 215 may be formed in layers 240. For example, the die seal 215-a may include a layer 240-a, a layer 240-b, a layer 240-c, and a layer 240-d in the example of FIG. 2A and the die seal 215-b may include a layer 240-e, a layer 240-f, a layer 240-g, and a layer 240-h in the example of FIG. 2B. The layer 240-a and the layer 240-e may be the top-most metal layers of the die seal 215 and the layer 240-d and the layer 240-h may be bottom-most metal layers of the die seal 215. In some examples, the die 255 may also include multiple layers and each layer 240 of the die seal 215 may correspond to (or be at the same level as) one or more layers of the die 255. In some examples, the die seal 215 may include a conductive material such as copper, silver, aluminum, graphite, etc. and in some examples, each layer 240 of the die seal 215 may include different conductive materials or a same conductive material. Further, in FIGS. 2A and 2B, the layers 240 of the die seal 215 are shown to be uniform and may be associated with the same thickness or width. However, it may be understood that the layers 240 of the die seal 215 may not be uniform. For example, the layer 240-a may be associated with a first width and the layer 240-b may be associated with a second width. The second width may be greater than the first width resulting in the layer 240-b extending into the space of the die 255-a more so than the layer 240-a. That is, the third surface of the four walls of the die seal 215 may not be smooth as illustrated in FIGS. 2A and 2B.

As described herein, another component that may be formed on the wafer 205 may be a conductive antenna 220 (e.g., a conductive antenna 220-a or a conductive antenna 220-b). The conductive antenna 220 may be described as a structure whose purpose is to detect charging of the die seal 215 (e.g., plasma-induced charging) and similar to the die seal 215, the conductive antenna 220 may include a conductive material such as such as copper, silver, aluminum, graphite, etc. In some examples, the conductive antenna 220 may surround the die seal 215. However, in some examples, the conductive antenna 220 may not be in direct contact with the die seal 215. Between the die seal 215 and the conductive antenna 220 may be an insulator 260 (e.g., an insulator 260-a or an insulator 260-b) made of dielectric material or any other type of insulating material. The insulator 260 may separate the two conductive structures such that no charge is exchanged between the two conductive structures. In some examples, the insulator 260 may be coupled with one or more layers 240 of the die seal 215 as well as the conductive antenna 220. Further, the conductive antenna 220 may include multiple segments that are separated from one another by gaps 225. FIG. 2A and FIG. 2B illustrate different segmentation examples of the conductive antenna 220.

In FIG. 2A, the conductive antenna 220-a may be split into 4 segments (e.g., a first segment (segment 1), a second segment (segment 2), a third segment (segment 3), and a fourth segment (segment 4)) and each of the segments may be parallel to or secured in a fixed position relative to at least one wall of the die seal 215 (e.g., the fourth surface of the respective wall of the die seal 215). In some examples, a shape of the conductive antenna 220-a may be such as to create a perimeter around the die 255-a (e.g., a square or a rectangle). In cases where the die 255-a is a square, the first segment may be parallel to the second segment and perpendicular to the third segment and the fourth segment. Further, if the shape of the conductive antenna 220-a is a rectangle, a length of the fourth segment and the third segment may be different from the length of the first segment and the second segment. For example, the length of the fourth segment and the third segment may be longer than the length of the first segment and the second segment

As shown in FIG. 2A, the gaps 225-a separating the segments from one another may correspond to areas (e.g., 2 areas) where the third segment does not contact the insulator 260-a coupled with the respective wall of the die seal 215-a (e.g., on either end of the third segment) and areas (e.g., 2 areas) where the fourth segment does not contact the insulator 260-a coupled with the respective wall of the die seal 215-a (e.g., on either end of the fourth segment). Further, in some examples, one or more of the segments may be in contact with the insulator 260-a that surrounds at least two walls of the die seal 215-a. For example, the first segment and the second segment may wrap around 2 corners of the die seal 215. While FIG. 2A shows gaps 225-a between segments at specific locations, the gaps 225-a being positioned at different locations in the conductive antenna 220-a. For example, the die 255-a in the bottom left corner and the die 255-a in the bottom right corner show alternative placements for the gaps 225-a. Segments of the conductive antenna may be formed by placing the gaps 225-b in any combinations of positions around the die.

In FIG. 2B, the conductive antenna 220-b may be split into 8 segments (e.g., a first segment (segment 1), a second segment (segment 2), a third segment (segment 3), a fourth segment (segment 4), a fifth segment (segment 5), a sixth segment (segment 6), a seventh segment (segment 7), and an eight segment (segment 8)) and each segment may be parallel to a wall of the die seal 215-b (e.g., the fourth surface of the respective wall of the die seal 215-b). In some examples, a pair of segments may be adjacent to a same wall of the die seal 215-b. For example, the first segment and the second segment may be adjacent to the same wall. In some examples, a shape of the conductive antenna 220-b may be a square or a rectangle. In such cases, the first segment and the second segment may be parallel to the third segment and the fourth segment and perpendicular to the fifth segment, the sixth segment, the seventh segment, and the eighth segment. In some examples, the length of the first segment, the second segment, the third segment, the fourth segment, the fifth segment, the sixth segment, the seventh segment, and the eight segment may be different from one another.

As shown in FIG. 2B, the gaps 225-b separating the segments from one another may correspond to areas where the segments of the conductive antenna 220-b do not contact the insulator 260-b coupled with the respective wall of the die seal 215-b. In some examples, one or more of the segments may be in contact with the insulator 260-b coupled with at least two walls of the die seal 215-b. For example, the first segment, the second segment, the third segments, and the fourth segment may wrap around a corner of the die seal 215. Although the shape of the conductive antennas 220 shown in FIGS. 2A and 2B is a rectangle or a square, it is understood that the conductive antennas 220 may not only form a rectangular or square shape, but other conductive antenna shapes are possible. While FIG. 2B shows gaps 225-b between segments at specific locations, the gaps 225-b being positioned at different locations in the conductive antenna. For example, the die 255-b in the bottom left corner and the die 255-b in the bottom right corner show alternative placements for the gaps 225-b. Segments of the conductive antenna may be formed by placing the gaps 225-b in any combinations of positions around the die.

In both the FIG. 2A and the FIG. 2B, the conductive antenna 220 (e.g., the conductive antenna 220-a and the conductive antenna 220-b) may be located in the top-most metal layer. For example, as shown in FIG. 2A and FIG. 2B, the conductive antenna 220 may be at a same level as the layer 240-a or the layer 240-e of the die seal 215. In some examples, the layer 240-a and the layer 240-e may be planar with the top-most metal layer of the die 255.

In addition to the die seal 215 and the conductive antenna 220, a passivation layer 230 (e.g., a passivation layer 230-a and a passivation layer 230-b) may be formed. The passivation layer 230 may be formed on the top surface of each die 255 and may be described as a protective barrier for the die 255. Further, the passivation layer 230 may include a dielectric material such as polyimide. In some examples, the passivation layer 230 may prevent the top surface of the die 255 from being exposed to plasma during manufacturing. As shown in FIGS. 2A and 2B, at least a portion of the conductive antenna 220 may not be covered by the passivation layer 230. In such examples, during plasma processes (e.g., during etching or deposition), the conductive antenna 220 may accumulate charge due to its conductive nature. In some examples, the conductive antenna 220 may be coupled with a sensor 235 (e.g., a sensor 235-a and a second 235-b) and the sensor 235 may generate a signal based on the charge accumulated in the conductive antenna 220. The signal may indicate that the die 255 is experiencing plasma induced damage. In other words, the signal may indicate that charge has accumulated in the die seal 215 from the plasma processes and has discharged quickly through the wafer 205 potentially damaging one or more components of the die 255.

Upon detection of the signal, the die 255 or a testing device coupled with the sensor 235 may determine that plasma induced damage has occurred on the die 255. In the case that the conductive antenna 220 includes multiple segments, the die 255 or the testing device coupled with the sensor 235 may also determine a location of the passivation layer over-etch based on which segment or segments resulted in a signal. For example, if a sensing circuit coupled with the first segment of FIG. 2A is the only segment to generate the signal, the die 255 or the testing device coupled with the sensor 235 may determine that the etching of the passivation layer has shifted to the right. Using this information, processes and machinery involved in passivation layer deposition or etching may be adjusted or shifted to ensure that the passivation layer is aligned. In some examples, increasing the number of segments may allow the die 255 or a testing device coupled with the sensor 235 to increase granularity of the location of the passivation layer over-etch.

In some examples, the conductive antenna 220 may not be coupled with the insulator 260. For example, the conductive antenna 220 may be located a distance (e.g., a distance of x) away from the insulator 260, but still may be at the same level as the top-most metal layer 240 as illustrated by the conductive antenna 220 represented by the dashed box in FIGS. 2A and 2B. In another example, the conductive antenna 220 may be located at the same level as a layer 240 lower than the topmost metal layer 240. For example, the conductive antenna 220 may be located at a same level as the layer 240-b or the layer 240-f of the die seal 215 as illustrated by the conductive antenna 220 represented by the dotted box in FIGS. 2A and 2B. The conductive antenna locations as illustrated in FIGS. 2A and 2B are merely exemplary and it may be understood that the conductive antenna 220 may be positioned in any of the layers 240 of the die seal 215 or any distance away from the die seal 215.

Further, other conductive antennas 220 may be formed around the die seal 215. The other conductive antennas 220 may also be coupled with a sensor 235 that is configured to generate a signal based on charge accumulating in the respective conductive antenna 220. The location of the other conductive antennas 220 with respect to the die seal 215 may slightly differ from one another. For example, multiple conductive antennas 220 may be positioned at different layers 240 of the die seal 215, different distances away from the die seal 215, or a combination of the two. Including other conductive antennas 220 at different locations may allow for a full characterization of areas of the die seal 215 that may be vulnerable to plasma processes (e.g., may be exposed to the plasma). Similar to increasing the number of segments of the conductive antenna 220, increasing the number of conductive antenna 220 may also allow the die 255 or a testing device coupled with the sensor 235 to increase granularity of the location of the over-etch.

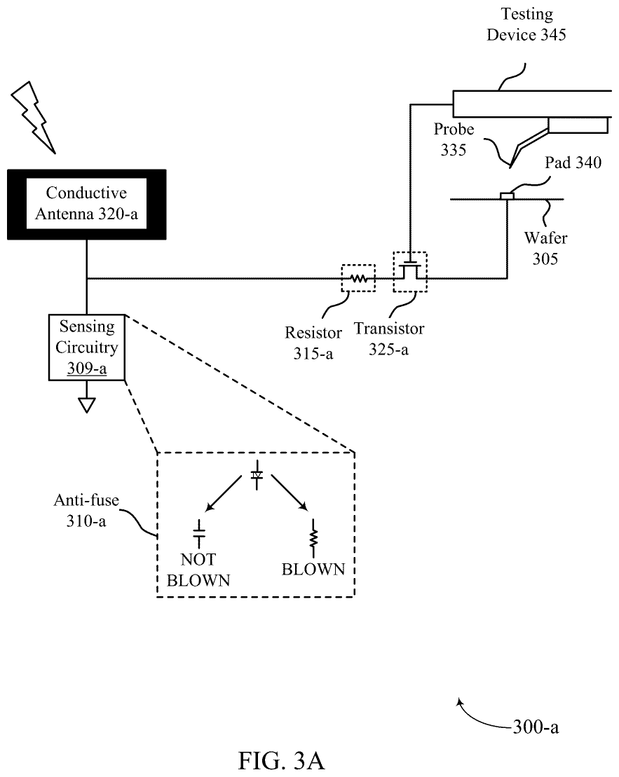

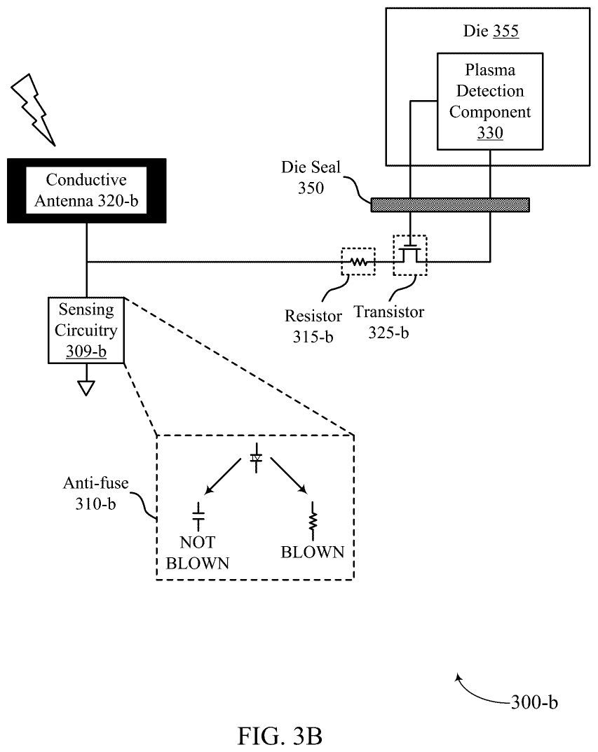

FIGS. 3A and 3B show examples of a circuit 300 (e.g., a circuit 300-a and a circuit 300-b) that supports plasma induced damage detection of a memory die in accordance with examples as disclosed herein. In some examples, the circuit 300-a and the circuit 300-b may implement, or be implemented by, aspects of the system 100 and the component diagrams 200 (e.g., the component diagram 200-a and the component diagram 200-b). For example, the circuit 300-a and the circuit 300-b may include a conductive antenna 320 which is an example of a conductive antenna 220 as described with reference to FIGS. 2A and 2B. Further, the circuit 300-b may include a die 355 which may be an example of a memory device 145 and a die 255 as described with reference to FIGS. 1, 2A, and 2B.

As described with reference to FIGS. 2A and 2B, a conductive antenna 320 may be coupled with a sensing circuit and the sensing circuit may be configured to generate a signal based on charge accumulating in the conductive antenna 320 due to exposure to plasma during manufacturing. In some examples, the sensing circuit may include sensing circuitry 309 (e.g., sensing circuitry 309-a and sensing circuitry 309-b). The sensing circuitry 309 may be coupled with ground and the conductive antenna 320. As shown in FIGS. 3A and 3B, the sensing circuitry 309 may be an example of an anti-fuse 310 (e.g., an anti-fuse 310-a or an anti-fuse 310-b). The anti-fuse 310 may be an example of programmable memory and may include a fusible dielectric material (e.g., a fusible oxide material). If the conductive antenna 320 is not exposed to plasma during manufacturing, little to no charge will accumulate in the conductive antenna 320 and thus, little to no voltage will be applied to the anti-fuse 310. In response to the lack of voltage applied to the anti-fuse 310, the anti-fuse 310 will not blow and will act as a capacitor. On the other hand, if the conductive antenna 320 is exposed to the plasma during manufacturing, charge may accumulate in the conductive antenna 320 and discharge to the anti-fuse 310 causing the anti-fuse 310 to blow. When blown, the anti-fuse 310 may act as a resistor. Alternatively, the sensing circuitry 309 may include a fuse or one-time programmable read only memory (ROM) which is not shown in FIGS. 3A and 3B.

In some examples, the sensing circuit may also include a resistor 315 and a transistor 325. An input of the resistor 315 may be coupled with the conductive antenna 320 and an output of the resistor 315 may be coupled with a first input node of the transistor 325. Further, a second input node (or gate) and an output node of the transistor 325 may be coupled with a testing device 345 as shown in FIG. 3A or a plasma detection component 330 of a die 355 (e.g., a die that the conductive antenna 320 surrounds) as shown in FIG. 3B. When blown, the anti-fuse 310 may create a conductive path from the conductive antenna 320 to the resistor 315 allowing current to flow from the conductive antenna 320 to the resistor 315 in the event that charge has accumulated in the conductive antenna 320. In some examples, the resistor 315 may be an example of a resistor that limits current (e.g., a current-limiting resistor). An example of a current-limiting resistor may be a ballast resistor which may increase resistance as current increases and reduce resistance as current decreases. The current may then flow to the transistor 325. Further, in some examples, the transistor 325 may be an example of a triple-well transistor.

In FIG. 3A, the second input (or gate) of the transistor 325-a may be coupled with a testing device 345 and the output of the transistor 325-a may be coupled with a pad 340 located on an external surface of a wafer 305. During a test mode, the testing device 345 may apply a voltage to the second input of the transistor 325-a allowing any current from the resistor 315-a to pass through to the pad 340. The testing device 345 may then perform probe testing. During probe testing, the testing device 345 may touch the probe 335 to the pad 340 and measure the current or voltage being applied to the pad 340. If the voltage or current exceeds a threshold, the testing device 345 may determine that the conductive antenna 320-a is exposed to the plasma and detect potential plasma induced damage to the die. Alternatively, if the voltage or current does not exceed the threshold, the testing device 345 may determine that the conductive antenna 320-a is not exposed to the plasma and may not detect plasma induced damage to the die.

In FIG. 3B, the second input (or gate) of the transistor 325-b and the output of the transistor 325-b may be coupled with a plasma detection component 330 of the die. During a test mode, the plasma detection component may apply a voltage to the second input of the transistor 325-b allowing any current from the resistor 315-b to pass through to the plasma detection component 330. The plasma detection component 330 may then measure the current or voltage output from the transistor 325-b. If the voltage or current exceeds a threshold, the plasma detection component 330 may determine that the conductive antenna 320-b is exposed to the plasma and detect potential plasma induced damage to the die. Alternatively, if the voltage or current does not exceed the threshold, the plasma detection component 330 may determine that the conductive antenna 320-b is not exposed to the plasma and may not detect plasma induced damage to the die. In some examples, the die seal 350 surrounding the die 355 may include tunnels or holes such that circuitry of the sensing circuit may pass through the die seal 350 and couple with the plasma detection component 330. In an alternative example, the plasma detection circuit 330 may be located outside of the die 355. In such examples, the circuitry of the sensing circuit may not pass through the die seal 350 and the die seal 305 may not include the tunnels or gaps.

As described with reference to FIGS. 2A and 2B, the conductive antenna 320 may include multiple segments. In such cases, each segment may be coupled with a respective sensing circuit. Segmentation of the conductive antenna 320 may allow the testing device 345 or the die 355 to determine how the passivation layer may be misaligned or over-etched. For example, if a sensing circuit associated with a conductive antenna coupled with a left wall of the die seal detects plasma induced damage and a sensing circuit associated with a conductive antenna coupled with a right wall of the die seal, the die 355 or the testing device 345 does not detect plasma induced damage, the die 355 or the testing device 345 may determine that deposition or etching of the passivation layer has shifted to the right. Using this information, processes and machinery involved in passivation layer deposition or etching may adjust to ensure that the passivation layer is aligned (fully covering the die 355).

An apparatus is described. The following provides an overview of aspects of the apparatus as described herein:

Aspect 1: A memory device, including: a memory die coupled with a substrate; a die seal structure surrounding the memory die and coupled with the substrate, the die seal structure including a plurality of layers; an insulator material coupled with at least one layer of the plurality of layers of the die seal structure, a conductive material coupled with the insulator material; and a sensing circuit coupled with the conductive material, the sensing circuit configured to generate a signal based on a charge accumulated in the conductive material.

Aspect 2: The memory device of aspect 1, where the die seal structure includes: a first surface that is adjacent to the substrate; a second surface that is opposite from the first surface; a third surface that is adjacent to the memory die; and fourth surface that is opposite from the third surface, where the conductive material is coupled with the fourth surface of the die seal structure.

Aspect 3: The memory device of any of aspects 1 and 2, where the conductive material includes one or more segments that are separated from one another by one or more gaps.

Aspect 4: The memory device of aspect 3, where the die seal structure includes a plurality of walls surrounding the memory die, each wall of the plurality of walls including a plurality of surfaces.

Aspect 5: The memory device of aspect 4, where the one or more segments include: a first segment that is secured in a fixed position relative to a surface of a first wall of the plurality of walls of the die seal structure; a second segment that is secured in a fixed position relative to a surface of a second wall of the plurality of walls of the die seal structure; a third segment that is secured in a fixed position relative to a surface of a third wall of the plurality of walls of the die seal structure; and a fourth segment that is secured in a fixed position relative to a surface of a fourth wall of the plurality of walls of the die seal structure.

Aspect 6: The memory device of aspect 5, where the first segment is parallel to the second segment and perpendicular to the third segment and the fourth segment, and a length of the first segment and a length of the second segment is shorter than a length of the third segment and a length of the fourth segment.

Aspect 7: The memory device of any of aspects 4 through 67, where the one or more segments include: a first segment that is secured in a fixed position relative to a surface of a first wall of the plurality of walls of the die seal structure and a surface of a second wall of the plurality of walls of the die seal structure; a second segment that is secured in a fixed position relative to the second wall of the plurality of walls of the die seal structure; a third segment that is secured in a fixed position relative to a surface of a third wall of the plurality of walls of the die seal structure and a surface of a fourth wall of the plurality of walls of the die seal structure; and a fourth segment that is secured in a fixed position relative to the surface of the fourth wall.

Aspect 8: The memory device of any of aspects 3 through 7, where each segment of the one or more segments is coupled with a respective sensing circuit.

Aspect 9: The memory device of any of aspects 1 through 8, where the sensing circuit includes: programmable memory coupled with ground and the conductive material; and a resistor coupled with the programmable memory and a first node of a transistor.

Aspect 10: The memory device of aspect 9, where a second node and a third node of the transistor is coupled with a testing device external to the memory die or a component internal to the memory die.

Aspect 11: The memory device of any of aspects 9 and 10, where the programmable memory includes a fusible dielectric material.

Aspect 12: The memory device of any of aspects 1 through 11, where the memory device further includes: a dielectric material that partially covers the conductive material, where the conductive material and the sensing circuit are configured to detect a partial coverage of the dielectric material over the die seal structure based on the dielectric material partially covering the conductive material.

Aspect 13: The memory device of any of aspects 1 through 12, including: a second conductive material secured in a fixed position relative to a second layer of the die seal structure different from the at least one layer of the plurality of layers of the die seal structure; and a second sensing circuit coupled with the second conductive material, the second sensing circuit configured to generate a second signal based on a charge accumulated in the second conductive material.

Aspect 14: The memory device of any of aspects 1 through 13, including: a second conductive material coupled with the conductive material, where a surface of the second conductive material oriented towards the die seal structure is a first distance away from a surface of the die seal structure and a surface of the conductive material oriented towards the die seal structure is a second distance away from the die seal structure; and a second sensing circuit coupled with the second conductive material, the second sensing circuit configured to generate a second signal based on a charge accumulated in the second conductive material.

Aspect 15: The memory device of any of aspects 1 through 14, where the conductive material and the sensing circuit are configured to detect the charge accumulated in the conductive material based on at least a portion of the conductive material being exposed to plasma.

Aspect 16: The memory device of any of aspects 1 through 14, where the at least one layer includes a topmost metal layer of the plurality of layers.

An apparatus is described. The following provides an overview of aspects of the apparatus as described herein:

Aspect 17: A memory device, including: a memory die coupled with a substrate; a die seal structure surrounding the memory die and coupled with the substrate; an insulator material coupled with the die seal structure, a conductive material coupled with the insulator material and including a plurality of segments that are separated from one another by one or more gaps; and a plurality of sensing circuits, each sensing circuit coupled with a respective segment of the plurality of segments and configured to generate a signal based on a charge accumulated in the respective segment.

Aspect 18: The memory device of aspect 17, where the die seal structure includes a plurality of walls surrounding the memory die, each wall of the plurality of walls including a plurality of surfaces.

Aspect 19: The memory device of aspect 18, where the plurality of segments include: a first segment that is secured in a fixed position relative to a surface of a first wall of the plurality of walls of the die seal structure; a second segment that is secured in a fixed position relative to a surface of a second wall of the plurality of walls of the die seal structure; a third segment that is secured in a fixed position relative to a surface of a third wall of the plurality of walls of the die seal structure; and a fourth segment that is secured in a fixed position relative to a surface of a fourth wall of the plurality of walls of the die seal structure.

Aspect 20: The memory device of aspect 19, where the first segment is parallel to the second segment and perpendicular to the third segment and the fourth segment, and a length of the first segment and a length of the second segment is shorter than a length of the third segment and a length of the fourth segment.

Aspect 21: The memory device of any of aspects 18 through 19, where the plurality of segments include: a first segment that is in contact with a surface of a first wall of the plurality of walls of the die seal structure and a surface of a second wall of the plurality of walls of the die seal structure; a second segment that is in contact with the surface of the second wall of the plurality of walls of the die seal structure; a third segment that is in contact with a surface of a third wall of the plurality of walls of the die seal structure and a surface of a fourth wall of the plurality of walls of the die seal structure; and a fourth segment that is in contact with the surface of the fourth wall.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, a wire, a conductive line, a conductive layer, or the like that provides a conductive path between components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processor, firmware, or any combination thereof. If implemented in software executed by a processor, the functions may be stored on or transmitted over as one or more instructions (e.g., code) on a computer-readable medium. Due to the nature of software, functions described herein can be implemented using software executed by a processor, hardware, firmware, hardwiring, or combinations of any of these. Features implementing functions may be physically located at various positions, including being distributed such that portions of functions are implemented at different physical locations.

Illustrative blocks and modules described herein may be implemented or performed with a processor, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processor. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium, or combination of multiple media, that can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a memory die coupled with a substrate;
a die seal structure surrounding the memory die and coupled with the substrate, the die seal structure comprising a plurality of layers;
an insulator material coupled with at least one layer of the plurality of layers of the die seal structure;
a conductive material coupled with the insulator material; and
a sensing circuit coupled with the conductive material, the sensing circuit configured to generate a signal based on a charge accumulated in the conductive material.

2. The memory device of claim 1, wherein the die seal structure comprises:
a first surface that is adjacent to the substrate;
a second surface that is opposite from the first surface;
a third surface that is adjacent to the memory die; and
fourth surface that is opposite from the third surface, wherein the conductive material is coupled with the fourth surface of the die seal structure.

3. The memory device of claim 1, wherein the conductive material comprises one or more segments that are separated from one another by one or more gaps.

4. The memory device of claim 3, wherein the die seal structure comprises a plurality of walls surrounding the memory die, each wall of the plurality of walls comprising a plurality of surfaces.

5. The memory device of claim 4, wherein the one or more segments comprise:
a first segment that is secured in a fixed position relative to a surface of a first wall of the plurality of walls of the die seal structure;
a second segment that is secured in a fixed position relative to a surface of a second wall of the plurality of walls of the die seal structure;
a third segment that is secured in a fixed position relative to a surface of a third wall of the plurality of walls of the die seal structure; and
a fourth segment that is secured in a fixed position relative to a surface of a fourth wall of the plurality of walls of the die seal structure.

6. The memory device of claim 5, wherein:
the first segment is parallel to the second segment and perpendicular to the third segment and the fourth segment, and
a length of the first segment and a length of the second segment is shorter than a length of the third segment and a length of the fourth segment.

7. The memory device of claim 4, wherein the one or more segments comprise:
a first segment that is secured in a fixed position relative to a surface of a first wall of the plurality of walls of the die seal structure and a surface of a second wall of the plurality of walls of the die seal structure;
a second segment that is secured in a fixed position relative to the surface of the second wall of the plurality of walls of the die seal structure;
a third segment that is secured in a fixed position relative to a surface of a third wall of the plurality of walls of the die seal structure and a surface of a fourth wall of the plurality of walls of the die seal structure; and
a fourth segment that is secured in a fixed position relative to the surface of the fourth wall.

8. The memory device of claim 3, wherein each segment of the one or more segments is coupled with a respective sensing circuit.

9. The memory device of claim 1, wherein the sensing circuit comprises:
programmable memory coupled with ground and the conductive material; and
a resistor coupled with the programmable memory and a first node of a transistor.

10. The memory device of claim 9, wherein a second node and a third node of the transistor is coupled with a testing device external to the memory die or a component internal to the memory die.

11. The memory device of claim 9, wherein the programmable memory comprises a fusible dielectric material.

12. The memory device of claim 1, wherein the memory device further comprises:
a dielectric material that partially covers the conductive material, wherein the conductive material and the sensing circuit are configured to detect a partial coverage of the dielectric material over the die seal structure based on the dielectric material partially covering the conductive material.

13. The memory device of claim 1, comprising:
a second conductive material secured in a fixed position relative to a second layer of the die seal structure different from the at least one layer of the plurality of layers of the die seal structure; and
a second sensing circuit coupled with the second conductive material, the second sensing circuit configured to generate a second signal based on a charge accumulated in the second conductive material.

14. The memory device of claim 1, comprising:
a second conductive material coupled with the conductive material, wherein a surface of the second conductive material oriented towards the die seal structure is a first distance away from a surface of the die seal structure and a surface of the conductive material oriented towards the die seal structure is a second distance away from the die seal structure; and
a second sensing circuit coupled with the second conductive material, the second sensing circuit configured to generate a second signal based on a charge accumulated in the second conductive material.

15. The memory device of claim 1, wherein the conductive material and the sensing circuit are configured to detect the charge accumulated in the conductive material based on at least a portion of the conductive material being exposed to plasma.

16. A memory device, comprising:
a memory die coupled with a substrate;
a die seal structure surrounding the memory die and coupled with the substrate;
an insulator material coupled with the die seal structure;
a conductive material coupled with the insulator material and comprising a plurality of segments that are separated from one another by one or more gaps; and
a plurality of sensing circuits, each sensing circuit coupled with a respective segment of the plurality of segments and configured to generate a signal based on a charge accumulated in the respective segment.

17. The memory device of claim 16, wherein the die seal structure comprises a plurality of walls surrounding the memory die, each wall of the plurality of walls comprising a plurality of surfaces.

18. The memory device of claim 17, wherein the plurality of segments comprise:
a first segment that is secured in a fixed position relative to a surface of a first wall of the plurality of walls of the die seal structure;
a second segment that is secured in a fixed position relative to a surface of a second wall of the plurality of walls of the die seal structure;
a third segment that is secured in a fixed position relative to a surface of a third wall of the plurality of walls of the die seal structure; and
a fourth segment that is secured in a fixed position relative to surface of a fourth wall of the plurality of walls of the die seal structure.

19. The memory device of claim 18, wherein:
the first segment is parallel to the second segment and perpendicular to the third segment and the fourth segment, and
a length of the first segment and a length of the second segment is shorter than a length of the third segment and a length of the fourth segment.

20. The memory device of claim 17, wherein the plurality of segments comprise:
a first segment that is secured in a fixed position relative to a surface of a first wall of the plurality of walls of the die seal structure and a surface of a second wall of the plurality of walls of the die seal structure;
a second segment that is secured in a fixed position relative to the surface of the second wall of the plurality of walls of the die seal structure;
a third segment that is secured in a fixed position relative to a surface of a third wall of the plurality of walls of the die seal structure and a surface of a fourth wall of the plurality of walls of the die seal structure; and
a fourth segment that is secured in a fixed position relative to the surface of the fourth wall.
